(19) United States
(12) Patent Application Publication
(10) Pub. No.: US 2026/0313942 A1
(43) Pub. Date: Oct. 8, 2026

(54) HIGH-QUALITY E-MODE GAN HEMT POWER SEMICONDUCTOR EPITAXIAL WAFER USING SI(100) GROWTH SUBSTRATE

(71) Applicant: WAVELORD CO., LTD., Gyeonggi-do (KR)

(72) Inventors: June O SONG, Gyeonggi-do (KR); Young hun HAN, Gyeonggi-do (KR); Hyun Chul LIM, Gyeonggi-do (KR); Yu Hyun BAK, Gyeonggi-do (KR)

(21) Appl. No.: 19/637,355

(22) Filed: Apr. 2, 2026

(30) Foreign Application Priority Data
Apr. 3, 2025 (KR) 10-2025-0043374
Apr. 1, 2026 (KR) 10-2026-0058722

(51) Int. Cl. H10D 30/47; H10D 62/10; H10D 62/40; H10D 62/815

(52) U.S. Cl. CPC H10D 30/475; H10D 62/102; H10D 62/405; H10D 62/8164

(57) ABSTRACT

A high-quality E-mode GaN HEMT power semiconductor epitaxial wafer using a Si(100) growth substrate according to the present invention comprises: a growth substrate having a Si(100) crystal structure; a first AlN layer formed on the growth substrate; a dislocation annihilation layer (DAL) formed on the first AlN layer and comprising a three-dimensional shaped structure; a second AlN layer formed on the dislocation annihilation layer; a GaN channel layer formed on the second AlN layer; a barrier layer formed on the GaN channel layer; and a p-type GaN layer formed on the barrier layer.

### CROSS-REFERENCE TO RELATED APPLICATIONS

This application claims the benefit and priority to Korean Patent Application Nos. 10-2025-0043374, filed on Apr.03, 2025 and 10-2026-0058722, filed on Apr. 01, 2026. The entire disclosures of the applications identified in this paragraph are incorporated herein by references.

### FIELD

The present invention pertains to the field of Group III nitride-based epitaxial growth technology for power semiconductors. More specifically, the present invention relates to a high-quality E-mode GaN HEMT power semiconductor epitaxial wafer that is capable of maintaining high-quality crystal characteristics despite having a thinned structure by using a Si(100) growth substrate (100).

### BACKGROUND

In the case of GaN HEMT-on-Si epitaxial wafers, which have recently attracted attention as next-generation power semiconductor materials, thick Si(111) growth substrates are generally used. However, Si(111) substrates are relatively expensive and have a technical limitation in that a semi-insulating GaN buffer layer doped with carbon (C) for leakage current blocking must be grown to a thickness of 5 μm or more, due to the low resistivity characteristics of the substrate itself.

As the total thickness of the epitaxial layer increases, thermo-mechanical stress accumulates due to the difference in thermal expansion coefficients between the substrate and the epitaxial layer, causing frequent warpage and cracking of the wafer, which leads to increased handling difficulty and reduced lithography precision in semiconductor fabrication processes (Fab).

In addition, a thick GaN buffer layer impedes the dissipation of heat generated inside the device, and when used in RF power amplifier applications, increases substrate parasitic capacitance, thereby degrading high-frequency performance.

Accordingly, there is an urgent need for a new epitaxial wafer structure that can reduce epitaxial layer thickness and effectively control crystal defects while using a low-cost substrate.

### SUMMARY

### Technical Problem

The present invention aims to lower the production cost of power semiconductors by using a Si(100) growth substrate that is relatively inexpensive and has excellent compatibility with standard CMOS processes.

In addition, the present invention aims to secure high-quality crystallinity while reducing the total epitaxial layer thickness to 2 μm or less without a separate thick GaN buffer layer, by introducing a three-dimensional dislocation annihilation layer (DAL) structure.

In addition, the present invention aims to suppress warpage and cracking of the wafer and improve process yield through a thin epitaxial structure.

In addition, the present invention aims to realize stable operation in both RF and power switch devices by reducing leakage current and maximizing breakdown voltage and heat dissipation characteristics through the combination of a high-resistivity substrate and an AlN lower region.

### Technical Solution

To solve the above problems, the present invention provides a structure comprising a growth substrate having a Si(100) crystal structure, a first AlN layer formed thereon, and a three-dimensional dislocation annihilation layer.

An active region comprising a second AlN layer, a GaN channel layer, and a barrier layer is formed on the dislocation annihilation layer, and a p-type GaN layer for Normally-off operation is disposed at the uppermost portion.

In particular, a high-resistivity substrate having a resistivity of 10 kΩ·cm or more is used as the growth substrate, and threading dislocations propagating from below are effectively controlled through the dislocation annihilation layer to improve crystal quality.

In addition, depending on the embodiment, a stress relief region comprising a superlattice structure or a graded aluminum composition between the second AlN layer and the channel layer is introduced to manage the overall stress.

### Advantageous Effects

According to the present invention, the following remarkable effects can be obtained.

First, production costs and process efficiency can be dramatically improved through the use of a low-cost Si(100) substrate and thinning of the epitaxial layer thickness.

Second, by introducing the dislocation annihilation layer structure, excellent crystal quality can be secured even at thin thicknesses, which is objectively demonstrated through low FWHM values in XRD analysis data.

Third, the combination of a high-resistivity substrate and an AlN-based lower region suppresses vertical leakage current and improves breakdown voltage, and the thin epitaxial structure promotes heat dissipation, maximizing the thermal reliability of the device.

Fourth, through the reduction of parasitic effects due to the thin active region structure, a practical foundation is provided for realizing stable and fast operating speeds across RF power amplifiers and power switch devices.

### BRIEF DESCRIPTION OF THE DRAWINGS

FIG. 1 is a cross-sectional view showing the basic stacked structure of an E-mode GaN HEMT power semiconductor epitaxial wafer according to an embodiment of the present invention.

FIG. 2 is a detailed view for explaining the microstructure of a dislocation annihilation layer (DAL) and the blocking mechanism of threading dislocations according to an embodiment of the present invention.

FIG. 3 is a view showing the structure of a stress relief region according to various embodiments of the present invention, illustrating a graded composition structure.

FIG. 4 is a view showing the structure of a stress relief region according to various embodiments of the present invention, illustrating a superlattice structure.

FIG. 5 is a view showing an interface improvement structure of an active region according to an embodiment of the present invention.

### DETAILED DESCRIPTION

Hereinafter, an E-mode GaN HEMT power semiconductor epitaxial wafer using a Si(100) growth substrate and a method of manufacturing the same according to the present invention will be described in detail with reference to the drawings.

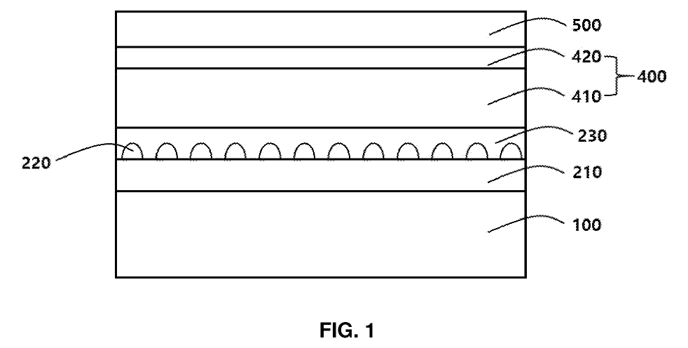

Referring to FIG. 1, an E-mode GaN HEMT power semiconductor epitaxial wafer according to an embodiment of the present invention adopts a growth substrate (100) having a Si(100) crystal structure in order to maximize productivity while maintaining high-quality device characteristics.

On the growth substrate (100), a first AlN layer (210), a dislocation annihilation layer (DAL) (220), and a second AlN layer (230) are sequentially stacked from the bottom, and an active region comprising a GaN channel layer (410) and a barrier layer (420) and a p-type GaN layer (500) for final E-mode operation are formed thereon.

The Si(100) wafer used as the growth substrate (100) is relatively inexpensive and has a standard thickness (0.725t), unlike the thick and expensive Si(111) substrate (1.15t) that was conventionally used, providing advantages in reducing process costs and achieving large-area scaling.

The first and second AlN layers (210, 230) formed on the growth substrate (100) serve as nucleation material layers, helping subsequent GaN-based layers to grow with high quality.

AlN possesses a very high bandgap energy of approximately 6.2 eV, providing an excellent vertical electric field blocking effect, and also functions as a heat sink that rapidly dissipates heat generated during device operation to the growth substrate (100) through its high thermal conductivity of 100 W/m·K or more.

The dislocation annihilation layer (DAL) (220) is inserted in a sandwich structure between the first AlN layer (210) and the second AlN layer (230) to form a physical bonding relationship.

The dislocation annihilation layer (DAL) (220) is composed of nano-sized three-dimensional shaped structures, and is responsible for reducing defect density by physically bending or blocking threading dislocations that originate at the interface of the growth substrate (100) and attempt to propagate upward.

The GaN channel layer (410) and the barrier layer (420) form a high-concentration two-dimensional electron gas (2DEG) channel at the interface through a hetero-junction structure, and the topmost p-type GaN layer (500) vertically depletes the channel region to complete the Normally-off characteristic in which no current flows even when no gate voltage is applied.

As a result, thanks to the dislocation control capability of the dislocation annihilation layer (DAL) (220), it has become possible to realize an epitaxial layer with a thin thickness of 2 μm or less, which previously had to be grown to 5 μm or more for securing crystal quality, and this directly leads to a reduction in epitaxial growth time and improvement in productivity.

In addition, the thin epitaxial structure reduces the thermo-mechanical stress of the wafer, minimizing the possibility of warpage and cracking, and by allowing the active region to be closely coupled with the high-resistivity Si(100) growth substrate (100), results in simultaneously improving mechanical stability and electrical operating speed.

Meanwhile, in this embodiment, the dislocation annihilation layer (DAL) (220) can be realized not only with AlN but also with nitride semiconductors such as AlGaN, GaN, InGaN, and AlInGaN, as well as insulating or nitride-based materials such as MgNX, SiNX, and SiO₂.

The barrier layer (420) can be formed by replacing the Al1-XGaXN material with Al1-XInXN depending on the design purpose, and if a change in the operating mode of the device is required, a D-mode (Normally-on) device can be flexibly realized by introducing a GaN cap layer or SiNX layer instead of the p-type GaN layer (500).

Next, an E-mode GaN HEMT power semiconductor epitaxial wafer according to another embodiment of the present invention includes all of the configurations of the previously described embodiment, but in particular adopts a high-resistivity Si(100) substrate (100) having a resistivity of 10 kΩ·cm or more as the growth substrate (100).

This is a component for maximizing the breakdown voltage of a power device and controlling unwanted current flow during device operation.

The high-resistivity Si(100) growth substrate (100) has a significantly higher resistivity value than a general silicon substrate, thereby effectively suppressing the spreading of a high electric field applied in the vertical direction of the device into the interior of the substrate (100).

These physical characteristics create an environment that fundamentally blocks leakage current flowing out through the growth substrate (100).

The growth substrate (100) is physically coupled with the first and second AlN layers (210, 230) and the DAL (220) structure, and in particular creates a synergy with the wide-bandgap AlN lower region to double the electric field blocking effect.

The use of the high-resistivity Si(100) growth substrate (100) improves the breakdown voltage characteristics of the device, ensuring stable switching operation even in high-voltage environments. In addition, by combining the excellent thermal conductivity inherent to the silicon substrate (100) with high-resistivity characteristics, heat generated in the GaN active region is rapidly dissipated through the substrate (100), while simultaneously reducing parasitic effects occurring in the substrate (100) during high-frequency operation, resulting in improved device reliability.

Meanwhile, depending on the required specifications of the device, in cases where extreme high-power environments are required, the growth substrate (100) can be replaced with a SiC substrate having a 4H structure with similar high-resistivity characteristics or a p-type substrate doped with a specific dopant.

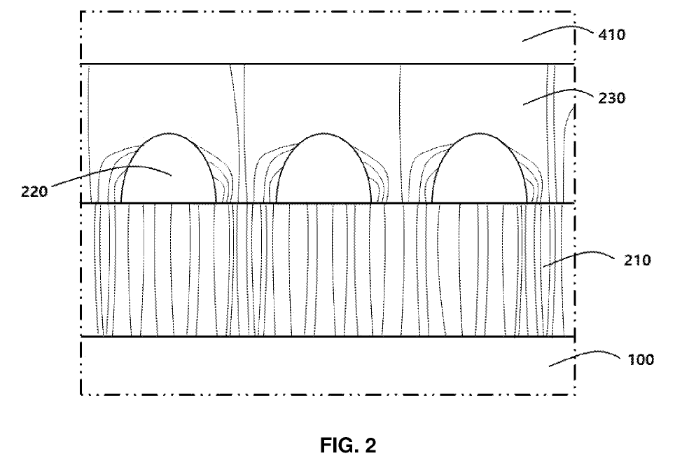

Referring to FIG. 2, an E-mode GaN HEMT power semiconductor epitaxial wafer according to another embodiment of the present invention includes the configuration of the previous embodiment, and comprises at least one selected from AlN, AlGaN, GaN, InGaN, AlInGaN, MgNX, SiNX, and SiO₂ as the material forming the dislocation annihilation layer (DAL) (220).

The materials forming the dislocation annihilation layer (DAL) (220) are formed as nano-sized three-dimensional shaped structures and serve to effectively control crystal defects propagating from the growth substrate (100).

Specifically, the materials forming the dislocation annihilation layer (DAL) (220) grow in a discontinuous island-shaped three-dimensional structure rather than a complete thin film form according to specific growth conditions when deposited on the first AlN layer (210).

The dislocation annihilation layer (220) is located between the lower first AlN layer (210) and the upper second AlN layer (230) and is physically coupled with them, creating a dislocation bending or dislocation blocking effect to dramatically reduce the crystal defect density of the upper GaN channel layer (410).

In particular, when SiNX or the like is utilized, the masking effect suppresses vertical propagation of dislocations and induces lateral dislocation coupling, enabling high-grade epitaxial layer quality.

The materials forming the dislocation annihilation layer (DAL) (220) can be used alone or configured in the form of a composite layer in which two or more materials are mixed, and can be implemented by adjusting the composition of the nitride semiconductor to optimize lattice matching according to design specifications.

Meanwhile, the vertical thickness of the dislocation annihilation layer (DAL) (220) is preferably in the range of 1 nm to 50 nm. This is the optimal numerical range for maximizing the dislocation annihilation effect while maintaining the thinning of the entire epitaxial wafer.

If the thickness of the dislocation annihilation layer (220) is less than 1 nm, the physical volume for blocking or bending dislocations may be insufficient, resulting in negligible defect control effects, and if it exceeds 50 nm, the layer itself may become a new source of defect generation or there is a risk of increasing the stress of the entire epitaxial layer.

The dislocation annihilation layer (220) is defined as a three-dimensional shaped structure in which nano-sized particle structures are arranged, rather than a simple planar layer. The particles are arranged in dot or island shapes that are spaced apart at predetermined intervals or partially connected on the surface of the first AlN layer (210).

In terms of the arrangement method, the three-dimensional structures are formed to preferentially cover regions where dislocations are concentrated in the first AlN layer (210), forming a physical barrier to prevent dislocations propagating from below from directly propagating to the upper second AlN layer (230) and the GaN channel layer (410).

According to this, a three-dimensional nanostructure formed within a thickness range of 1 nm to 50 nm bends the ends of dislocations so that they meet and annihilate each other, ultimately resulting in a dramatic improvement in the XRD FWHM of the GaN channel layer (410).

The density and particle size of the three-dimensional structures described above can be variously modified by controlling growth temperature, time, and gas partial pressure, and can also be implemented in a manner that gradually increases dislocation blocking efficiency by arranging them in a multilayer form rather than a single layer. As one example, the specific growth process conditions for forming the three-dimensional shaped structures of the dislocation annihilation layer (DAL) (220) are as follows. First, without supplying a nitrogen (N) source including ammonia (NH₃) above the first AlN layer (210), metal-organic (MO) sources of Group III elements (Al, Ga, In) are pre-flowed (Preflow) under conditions of a growth temperature in the range of 600°C to 1300°C, a growth pressure in the range of 30 torr to 400 torr, and a V/III ratio in the range of 300 to 4,000, in a mixed N₂/H₂ atmosphere, whereby the Group III elements aggregate with one another through a pyrolysis reaction to form three-dimensional nitride structures that are three-dimensional dot (Dot)-shaped precursor clusters (Precursor Clusters). Subsequently, a nitrogen source including ammonia (NH₃) is supplied to the three-dimensional nitride structures to recrystallize the three-dimensional nitride structures into a single crystal, thereby completing the dislocation annihilation layer (DAL) (220). By repeating this two-step process one or more times, the thickness of the dislocation annihilation layer (DAL) (220) and the tendency of variation in the lateral compositional ratio can be controlled according to the intended purpose.

Next, it is preferable that the thicknesses of the first AlN layer (210) and the second AlN layer (230) are each formed in the range of 10 nm to 100 nm.

If the thickness of each layer is less than 10 nm, it may be difficult to form a continuous thin film for suppressing reaction with the substrate (100) or inducing high-quality epitaxial growth. On the other hand, if it exceeds 100 nm, there is a concern that new cracks may occur due to the high critical thickness problem of AlN itself, or the epitaxial process time may increase unnecessarily. Therefore, the thickness range of 10 nm to 100 nm is the optimal range for maximizing the electric field blocking effect utilizing the high bandgap (6.2 eV) of AlN and the heat dissipation characteristics utilizing the high thermal conductivity, while simultaneously achieving thinning of the entire epitaxial layer.

This is a configuration for providing an optimal nucleation environment for controlling lower dislocations and securing the crystallinity of the upper channel layer (410).

Specifically, the first AlN layer (210) is formed directly above the Si(100) growth substrate (100) and serves as a seed layer for alleviating the lattice mismatch between silicon and nitride semiconductors, while the second AlN layer (230) planarizes the curved surface created by the dislocation annihilation layer (DAL) (220) and provides a base on which the upper GaN channel layer (410) can grow stably.

The first and second AlN layers (210, 230) form a coupling relationship that vertically surrounds the dislocation annihilation layer (DAL) (220), physically supporting and protecting the dislocation blocking effect by the dislocation annihilation layer (DAL) (220).

In this embodiment, the thicknesses of the first AlN layer (210) and the second AlN layer (230) can be set differently from each other depending on the voltage withstand characteristics of the device, or various deposition methods can be selected and implemented.

Next, an E-mode GaN HEMT power semiconductor epitaxial wafer according to another embodiment of the present invention includes the configuration of the previous embodiment, and further comprises a stress relief region (300) comprising at least one AlGaN thin film layer (300) formed between the second AlN layer (230) and the GaN channel layer (410).

This is a configuration for gradually relieving physical stress generated by the difference in lattice constants between heterogeneous materials.

The stress relief region (300) serves as a buffer zone between the lower AlN layers (210, 230) having high physical rigidity and the relatively ductile GaN channel layer (410) above.

The stress relief region (300) is formed directly on the upper surface of the second AlN layer (230) and has a coupling relationship in contact with the upper GaN channel layer (410), inducing compressive stress generated at the interface to offset the tensile stress generated when GaN cools on the growth substrate (100).

The effect of this is suppression of wafer warpage and cracking. The presence of the stress relief region (300) makes it possible to effectively control the thermo-mechanical stress accumulated inside the epitaxial layer without forming the total epitaxial thickness thick, which leads to improved wafer handling precision in subsequent semiconductor processes.

The stress relief region (300) can be formed using a single-composition AlGaN layer or by overlapping a plurality of composition layers as needed, and can be implemented by adjusting the aluminum (Al) content.

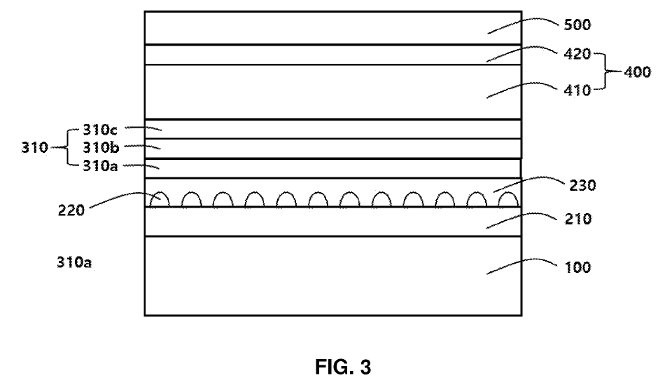

Next, referring to FIG. 3, an E-mode GaN HEMT power semiconductor epitaxial wafer according to another embodiment of the present invention has a structure in which the stress relief region (300) comprises a plurality of AlGaN thin film layers and the aluminum composition gradually or stepwise decreases toward the top.

The plurality of AlGaN thin film layers form a graded composition structure (310) designed to smoothly transition from the lower AlN composition to the upper GaN composition.

Each layer has a coupling relationship in which the crystal lattices are sequentially matched with adjacent layers, which minimizes the generation of dislocations due to lattice mismatch while also increasing stress relief efficiency.

According to this, by stepwise decreasing the aluminum composition, dislocation bending inside the epitaxial layer is additionally induced to further improve crystal quality. In addition, the total thickness of the stress relief region (300) can be formed thinly at less than 200 nm. High-quality epitaxy can be realized without the thick buffer layers reaching several μm in the prior art, simultaneously achieving production cost reduction and parasitic capacitance reduction effects.

In this embodiment, the graded composition structure (310) can be implemented by linearly and continuously varying the composition change, or by adjusting the thickness of each layer.

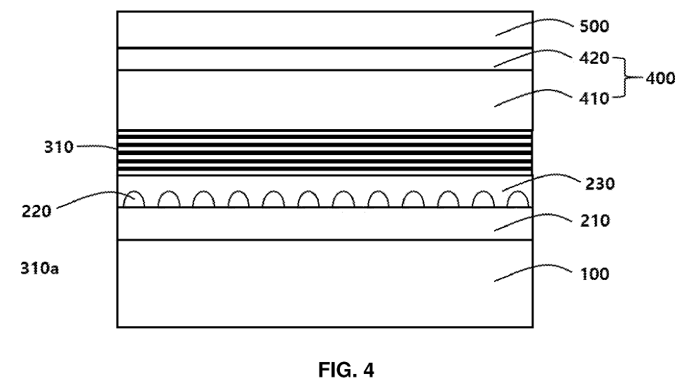

Next, referring to FIG. 4, an E-mode GaN HEMT power semiconductor epitaxial wafer according to another embodiment of the present invention includes a superlattice structure (310) in which the stress relief region (300) comprises alternately and repeatedly stacked high-composition AlGaN layers and low-composition AlGaN layers.

The high-composition layers are formed with an Al composition of 15-100% and a thickness of 1-5 nm, the low-composition layers are formed with an Al composition of 0-25% and a thickness of 5-30 nm, and the total thickness is maintained at 200 nm or less.

The superlattice structure (310) has structural characteristics in which ultra-thin film layers having different lattice constants are repeatedly bonded over tens of periods.

This structure provides a powerful defect filtering mechanism that causes residual dislocations propagating from below to be refracted in the lateral direction or annihilated each time they pass through multiple interfaces.

The superlattice structure (310) functions as a multiple barrier that blocks the vertical movement of dislocations between the second AlN layer (230) and the GaN channel layer (410).

The effects of this are securing extremely low dislocation density and precise stress control. The superlattice structure (310) disperses the elastic energy inside the epitaxial layer to maintain the flatness of the wafer at its best, ensuring the high-uniformity epitaxial quality required for high-power and high-frequency devices. In addition, by maximizing these effects within a thin thickness of 200 nm or less, it has the advantage of minimizing the heat dissipation path to the growth substrate (100).

In this embodiment, implementation can be carried out by adjusting the number of repetition periods of the superlattice or by finely tuning the composition of each layer.

Next, an E-mode GaN HEMT power semiconductor epitaxial wafer according to another embodiment of the present invention limits the thickness of the GaN channel layer (410) to a range of 50 nm to 500 nm.

This is a configuration for securing high electron mobility characteristics as the active region (400) of a power device while minimizing parasitic effects with the substrate (100) by maintaining the total epitaxial layer thickness thin.

The GaN channel layer (410) is formed directly on the lower second AlN layer (230) or the stress relief region (300), and has a structure in which the barrier layer (420) is stacked on top.

In the present invention, since defects propagating from below are effectively blocked through the action of the dislocation annihilation layer (DAL) (220), a high-quality channel region (410) with low crystal defect density is formed within the limited thickness range even without the thick buffer layers in units of several μm required in the prior art.

According to this, since the GaN channel layer (410) has a thin structure of 500 nm or less, the distance to the high-resistivity Si(100) growth substrate (100) is shortened, and a substrate parasitic capacitance reduction effect can be expected, which ensures excellent performance in high-frequency applications such as RF power amplifiers. That is, it manifests as improved operating speed of the device and stabilized wafer quality. In addition, the thin channel structure (410) contributes to resolving wafer warpage issues by reducing thermo-mechanical stress.

In this embodiment, implementation can be carried out by controlling unintentional doping levels or by finely adjusting the thickness.

Next, an E-mode GaN HEMT power semiconductor epitaxial wafer according to another embodiment of the present invention limits the barrier layer (420) to be composed of Al1-XGaXN or Al1-XInXN material and to have a thickness in the range of 10 nm to 50 nm.

This is a configuration for inducing strong polarization phenomena through hetero-junction with the channel layer (410) and securing a stable electron channel.

The barrier layer (420) is formed on the upper surface of the GaN channel layer (410) and is coupled with lattice matching at the interface.

The aluminum or indium composition of the barrier layer (420) determines the energy bandgap difference with the channel (410), thereby inducing the formation of a high-concentration two-dimensional electron gas (2DEG) at the interface without artificial doping.

The thickness range of 10 nm to 50 nm is the optimal value designed to maintain sufficient polarization intensity while ensuring that the deformation energy inside the layer does not exceed the critical value.

According to this, the barrier layer (420) of limited material and thickness provides high electron density and mobility, lowering the on-resistance of the device. In addition, maintaining appropriate thickness enables higher gate control efficiency when combined with the upper p-type GaN layer (500), making it possible to secure stable threshold voltage.

In this embodiment, the barrier layer (420) can be implemented by adopting a graded composition barrier structure or using a complex stacked structure.

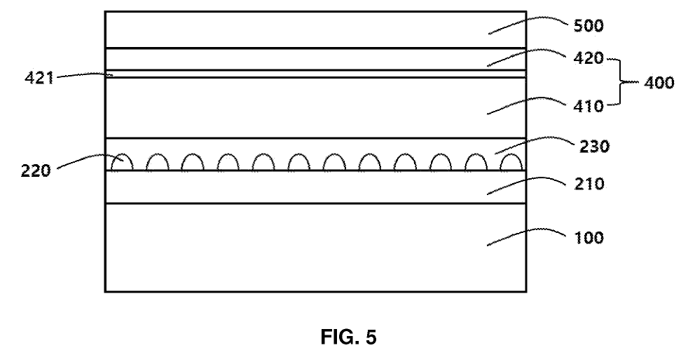

Next, referring to FIG. 5, an E-mode GaN HEMT power semiconductor epitaxial wafer according to another embodiment of the present invention includes a configuration for additionally forming an ultra-thin AlN thin film (421) with a thickness of less than 2 nm on the GaN channel layer (410) prior to formation of the barrier layer (420).

This is a functional configuration for improving the interface quality between the GaN channel layer (410) and the barrier layer (420) and suppressing electron scattering.

The ultra-thin AlN thin film (421) serves to prevent alloy scattering and locally increase the height of the energy barrier.

The ultra-thin AlN thin film (421) is preferably controlled to an ultra-thin film thickness of less than 2 nm in order to optimize electrical connectivity while suppressing dislocation generation due to lattice mismatch.

The effect of the ultra-thin AlN thin film (421) is an increase in the confinement effect of the two-dimensional electron gas (2DEG) and the resulting improvement in electron mobility. This results in simultaneously improving the high-frequency characteristics and power efficiency of the device.

In this embodiment, instead of the ultra-thin AlN thin film (421), implementation can be carried out by using an AlGaN layer with a very high aluminum composition or by controlling the growth temperature.

Next, an E-mode GaN HEMT power semiconductor epitaxial wafer according to another embodiment of the present invention forms the p-type GaN layer (500) with a thickness in the range of 2 nm to 100 nm.

This is a configuration for realizing Normally-off characteristics for safe driving of a power semiconductor and controlling gate leakage current.

The p-type GaN layer (500) is formed at the uppermost portion of the barrier layer (420) and is physically coupled with the region where the gate electrode is disposed.

The p-type GaN layer (500) forms a coupling relationship that upwardly bends the energy band of the lower channel region (410) by p-type impurities doped therein, depleting the 2DEG channel when no gate voltage is applied.

The thickness of approximately 100 nm is a range capable of minimizing the overall resistance component of the device while sufficiently maintaining such a depletion effect.

The p-type GaN layer (500) in the limited thickness range stably ensures E-mode operation in which the device maintains a blocking state at 0V (Zero Gate Voltage) gate voltage. This contributes to circuit protection and power consumption reduction at the system level.

In this embodiment, when a change in the operating mode of the device is required, a D-mode device can also be realized by forming a GaN cap layer or SiNX layer in place of the p-type GaN layer (500).

Next, an E-mode GaN HEMT power semiconductor epitaxial wafer according to another embodiment of the present invention has a crystal structure that satisfies XRD Rocking Curve measurement data within a specific numerical range.

Specifically, the crystallinity of the epitaxial wafer satisfies the range in which the FWHM at the GaN (002) plane is 400 arcsec or less, and the FWHM at the GaN (102) plane is 450 arcsec or less. This is a factor demonstrating that the combination of the high-resistivity Si(100) substrate (100) and the DAL (220) structure has significantly reduced crystal defect density.

The XRD measurement data is a physical indicator reflecting lattice distortion and dislocation density inside GaN crystals. The present invention realizes high-quality crystals, in contrast to the conventional structure which exhibits high values of 500 arcsec or more at GaN (002) and 800 arcsec or more at GaN (102).

This crystallinity is achieved by the DAL (220) structure forming a coupling relationship that physically blocks and annihilates dislocations.

The wafer having crystallinity within the limited range minimizes scattering of charge carriers to ensure high electron mobility, and suppresses leakage current to maximize breakdown voltage characteristics. In addition, trap effects are reduced to improve the reliability and operating speed of the device.

### DESCRIPTION OF REFERENCE NUMERALS

100: growth substrate (Si(100)), 210: first AlN layer, 220: dislocation annihilation layer (DAL), 230: second AlN layer, 300: stress relief region (AlGaN layers), 310: superlattice structure, 400: active region, 410: GaN channel layer, 420: barrier layer (AlGaN or AlInN), 421: ultra-thin AlN thin film, 500: p-type GaN layer (pGaN)

What is claimed is:

1. An E-mode GaN HEMT power semiconductor epitaxial wafer using Si(100) growth substrate, comprising:
a growth substrate having a Si(100) crystal structure;
a first AlN layer formed on the growth substrate;
a dislocation annihilation layer (DAL) formed on the first AlN layer and comprising a three-dimensional shaped structure;
a second AlN layer formed on the dislocation annihilation layer;
a GaN channel layer formed on the second AlN layer;
a barrier layer formed on the GaN channel layer; and
a p-type GaN layer formed on the barrier layer.

2. The E-mode GaN HEMT power semiconductor epitaxial wafer using Si(100) growth substrate of claim 1, wherein the growth substrate is a high-resistivity Si(100) substrate having a resistivity of 10 kΩ·cm or more.

3. The E-mode GaN HEMT power semiconductor epitaxial wafer using Si(100) growth substrate of claim 1, wherein the dislocation annihilation layer (DAL) is a nano-sized three-dimensional shaped structure comprising at least one selected from AlN, AlGaN, GaN, InGaN, AlInGaN, MgNX, SiNX, and SiO₂.

4. The E-mode GaN HEMT power semiconductor epitaxial wafer using Si(100) growth substrate of claim 1, wherein the dislocation annihilation layer (DAL) has a thickness in a range of 1 nm to 50 nm.

5. The E-mode GaN HEMT power semiconductor epitaxial wafer using Si(100) growth substrate of claim 1, wherein the first AlN layer and the second AlN layer each have a thickness in a range of 10 nm to 100 nm.

6. The E-mode GaN HEMT power semiconductor epitaxial wafer using Si(100) growth substrate of claim 1, further comprising a stress relief region comprising at least one AlGaN thin film layer formed between the second AlN layer and the GaN channel layer.

7. The E-mode GaN HEMT power semiconductor epitaxial wafer using Si(100) growth substrate of claim 6, wherein the stress relief region comprises a plurality of AlGaN thin film layers, wherein an aluminum (Al) composition gradually or stepwise decreases toward the top, and a total thickness of the stress relief region is less than 200 nm.

8. The E-mode GaN HEMT power semiconductor epitaxial wafer using Si(100) growth substrate of claim 6, wherein the stress relief region comprises a superlattice structure in which high-composition AlGaN layers having an Al composition of 15-100% and a thickness of 1-5 nm and low-composition AlGaN layers having an Al composition of 0-25% and a thickness of 5-30 nm are alternately stacked.

9. The E-mode GaN HEMT power semiconductor epitaxial wafer using Si(100) growth substrate of claim 1, wherein the GaN channel layer has a thickness in a range of 50 nm to 500 nm.

10. The E-mode GaN HEMT power semiconductor epitaxial wafer using Si(100) growth substrate of claim 1, wherein the barrier layer is composed of Al1-XGaXN or Al1-XInXN material and has a thickness in a range of 10 nm to 50 nm.

11. The E-mode GaN HEMT power semiconductor epitaxial wafer using Si(100) growth substrate of claim 1, further comprising an ultra-thin AlN thin film having a thickness of less than 2 nm formed on the GaN channel layer prior to formation of the barrier layer.

12. The E-mode GaN HEMT power semiconductor epitaxial wafer using Si(100) growth substrate of claim 1, wherein the p-type GaN layer has a thickness in a range of 2 nm to 100 nm.

13. The E-mode GaN HEMT power semiconductor epitaxial wafer using Si(100) growth substrate of claim 1, wherein as measured by XRD Rocking Curve analysis, the epitaxial wafer has a crystallinity in which a full width at half maximum (FWHM) of the GaN (002) plane is 400 arcsec or less and a FWHM of the GaN (102) plane is 450 arcsec or less.
